(19) United States
(12) Patent Application Publication
(10) Pub. No.: US 2026/0047189 A1
(43) Pub. Date: Feb. 12, 2026

(54) SEMICONDUCTOR DEVICE AND METHOD OF MANUFACTURING THE SAME

(71) Applicant: Renesas Electronics Corporation, Tokyo (JP)

(72) Inventor: Tadashi YAMAGUCHI, Tokyo (JP)

(21) Appl. No.: 19/230,264

(22) Filed: Jun. 6, 2025

(30) Foreign Application Priority Data
Aug. 6, 2024 (JP) 2024-129919

(51) Int. Cl. H10D 84/80; H01L 21/263; H01L 21/3205; H10D 1/00; H10D 1/40; H10D 12/00; H10D 12/01; H10D 62/10; H10D 64/23; H10D 64/62; H10D 64/64

(52) U.S. Cl. CPC H10D 84/817; H01L 21/2633; H01L 21/32053; H10D 1/025; H10D 1/40; H10D 12/038; H10D 12/481; H10D 62/127; H10D 64/232; H10D 64/62; H10D 64/64

(57) ABSTRACT

In a contact hole, a first side surface of an interlayer insulating film is separated from a second side surface of a first conductive film so that a part of an upper surface of the first conductive film is exposed from the interlayer insulating film. In the contact hole, a third side surface of an insulating film is separated from the second side surface of the first conductive film so that a part of the lower surface of the first conductive film is exposed from the insulating film. A plug includes a silicide layer formed on the second side surface of the first conductive film, a barrier metal film formed on the silicide layer, and a second conductive film formed on the barrier metal film.

### CROSS-REFERENCE TO RELATED APPLICATIONS

The disclosure of Japanese Patent Application No. 2024-129919 filed on Aug. 6, 2024, including the specification, drawings and abstract is incorporated herein by reference in its entirety.

### BACKGROUND

The present invention relates to a semiconductor device and a method for manufacturing the same, particularly to a semiconductor device with contact holes formed in an interlayer insulating film and a method for manufacturing the same.

As power devices, power MOSFETs (Metal Oxide Semiconductor Field Effect Transistors) and IGBTs (Insulated Gate Bipolar Transistors) with vertical trench gate structures are known. Some semiconductor devices (semiconductor chips) equipped with power devices include a resistance region in addition to the cell region where the main device is formed.

There are disclosed techniques listed below.
[Patent Document 1] Japanese Unexamined Patent Application Publication No. 2023-128002

For example, Patent Document 1 discloses a semiconductor device equipped with an IGBT and a resistive element. This resistive element is formed on an insulating layer and covered by an interlayer insulating film. Contact holes are formed in the interlayer insulating film, and plugs are embedded in these contact holes. One end of the resistive element is electrically connected to the gate electrode of the IGBT via a plug and gate wiring, while the other end of the resistive element is electrically connected to the gate wiring via a plug. A gate pad is formed on a part of the gate wiring to which the other end of the resistive element is connected.

### SUMMARY

Below, using FIG. 27, a semiconductor device example studied by the present inventors is described. This semiconductor device includes an IGBT and a resistive element. The resistive element is formed in a conductive film PL. One end of the resistive element is electrically connected to the gate electrode of the IGBT via a plug PG, and the other end of the resistive element is electrically connected to the gate pad via a plug PG. In other words, the resistive element is connected between the gate electrode and the gate pad of the IGBT. FIG. 27 shows, for example, the structure of the plug PG connected to one end of the resistive element.

As shown in FIG. 27, the plug PG includes a barrier metal film BM1, a barrier metal film BM2, and a conductive film CF, with the barrier metal film BM1 in contact with the conductive film PL that constitutes the resistive element. The conductive film PL that constitutes the resistive element is made of a polycrystalline silicon film. The barrier metal film BM1 is a titanium film, the barrier metal film BM2 is a titanium nitride film, and the conductive film CF is a tungsten film. The contact between the polycrystalline silicon film and the barrier metal film BM1 forms a Schottky junction. Due to the presence of interface defects in the polycrystalline silicon film, variations in the Schottky barrier occur, resulting in resistance value variations in the resistive element formed in the conductive film PL. For example, resistance value variations affect the turn-on time of the IGBT, thereby reducing the reliability of the semiconductor device.

The main objective of the present application is to suppress the resistance value variations of the resistive element as described above and to improve the reliability of the semiconductor device. Other problems and novel features will become apparent from the description of this specification and the accompanying drawings.

A brief overview of the typical embodiments disclosed in the present application is as follows.

In one embodiment, the semiconductor device includes a semiconductor substrate with an upper surface and a lower surface, an insulating film formed on the upper surface of the semiconductor substrate, a first conductive film formed on the insulating film, an interlayer insulating film formed on the upper surface of the semiconductor substrate to cover the first conductive film, a contact hole formed in the interlayer insulating film, the first conductive film, and the insulating film, and a plug embedded in the contact hole. In the contact hole, the first side of the interlayer insulating film is separated from the second side of the first conductive film so that a part of the upper surface of the first conductive film is exposed from the interlayer insulating film, and the third side of the insulating film is separated from the second side of the first conductive film so that a part of the lower surface of the first conductive film is exposed from the insulating film. The plug includes a silicide layer formed on the second side of the first conductive film, a barrier metal film formed on the silicide layer, and a second conductive film formed on the barrier metal film.

The method for manufacturing a semiconductor device in one embodiment includes the steps of: (a) preparing a semiconductor substrate with an upper surface and a lower surface, (b) forming an insulating film on the upper surface of the semiconductor substrate after step (a), (c) forming a first conductive film on the insulating film after step (b), (d) forming an interlayer insulating film on the upper surface of the semiconductor substrate to cover the first conductive film after step (c), (e) performing anisotropic dry etching on the interlayer insulating film, the first conductive film, and the insulating film to form a contact hole after step (d), (f) performing isotropic etching on the interlayer insulating film and the insulating film after step (e), and (g) embedding a plug in the contact hole after step (f). In step (f), the first side of the interlayer insulating film is separated from the second side of the first conductive film so that a part of the upper surface of the first conductive film is exposed from the interlayer insulating film, and the third side of the insulating film is separated from the second side of the first conductive film so that a part of the lower surface of the first conductive film is exposed from the insulating film. Step (g) includes: (g1) performing heat treatment on the semiconductor substrate in a hydrogen atmosphere after step (f), (g2) forming a silicide layer on the second side of the first conductive film in the contact hole after step (g1), (g3) forming a barrier metal film on the silicide layer after step (g2), and (g4) forming a second conductive film on the barrier metal film after step (g3).

A method of manufacturing a semiconductor device in an embodiment is a method of manufacturing a semiconductor device having a first region and a second region different from the first region. The method comprises (a) preparing a semiconductor substrate having an upper surface and a lower surface, (b) after (a), forming a first insulating film across the interior of the semiconductor substrate from a position higher than the upper surface of the semiconductor substrate in the first region, (c) after (b), forming a trench in the semiconductor substrate of the second region on the upper surface side of the semiconductor substrate, (d) after (c), forming a gate insulating film in the trench, (e) after (d), forming a gate electrode on the gate insulating film so as to fill the trench, (f) after (e), forming a second insulating film having a thickness thinner than the first insulating film on the upper surface of the semiconductor substrate of the first region and the second region, so as to cover the first insulating film in the first region and the gate electrode in the second region, (g) after (f), forming a first conductive film on the second insulating film in the first region and the second region, (h) after (g), removing the first conductive film and the second insulating film so that the first conductive film and the second insulating film are selectively left on the first insulating film, (i) after (h), forming a first impurity region of a first conductivity type in the semiconductor substrate of the second region on the upper surface side of the semiconductor substrate, with a bottom of the first impurity region positioned above a bottom of the trench, (j) after (i), forming a second impurity region of a second conductivity type opposite to the first conductivity type in the first impurity region, (k) after (j), forming an interlayer insulating film on the upper surface of the semiconductor substrate of the first region and the second region, so as to cover the first conductive film in the first region and the gate electrode, the first impurity region, and the second impurity region in the second region, (l) after (k), performing a planarization process on the interlayer insulating film of the first region and the second region by CMP method to flatten the upper surface of the interlayer insulating film, (m) after (l), performing anisotropic dry etching on the interlayer insulating film, the first conductive film, the second insulating film, and the first insulating film to form a first contact hole in the interlayer insulating film, the first conductive film, the second insulating film, and the first insulating film of the first region, with a bottom of the first contact hole positioned in the first insulating film, and to form a second contact hole in the interlayer insulating film, the second impurity region, and the first impurity region of the second region, with a bottom of the second contact hole positioned in the first impurity region, (n) after (m), performing isotropic etching on the interlayer insulating film, the second insulating film, and the first insulating film, and (o) after (n), embedding a first plug in the first contact hole and a second plug in the second contact hole. By (n), in the first contact hole, a first side surface of the interlayer insulating film is separated from a second side surface of the first conductive film so that a part of an upper surface of the first conductive film is exposed from the interlayer insulating film. By (n), in the first contact hole, a third side surface of the first insulating film and the second insulating film is separated from the second side surface of the first conductive film so that a part of a lower surface of the first conductive film is exposed from the first insulating film and the second insulating film. By (n), in the second contact hole, a fourth side surface of the interlayer insulating film is spaced apart from a fifth side surface of the second impurity region so that a part of an upper surface of the second impurity region is exposed from the interlayer insulating film. (o) includes (o1) after (n), performing heat treatment on the semiconductor substrate in a hydrogen atmosphere, (o2) after (o1), forming a first silicide layer on the second side surface of the first conductive film in the first contact hole and forming a second silicide layer on a part of an upper surface of the second impurity region and on the fifth side surface of the second impurity region in the second contact hole, (o3) after (o2), forming a first barrier metal film on the first silicide layer and the second silicide layer, and (o4) after (o3), forming a second conductive film on the first barrier metal film.

According to one embodiment, the reliability of the semiconductor device can be improved.

### BRIEF DESCRIPTION OF THE DRAWINGS

FIG. 1 is a plan view showing the entirety of a semiconductor device according to the embodiment.

FIG. 2 is a plan view showing the semiconductor device according to the embodiment.

FIG. 3 is a plan view showing the semiconductor device according to the embodiment.

FIG. 4 is an equivalent circuit diagram of the semiconductor device according to the embodiment.

FIG. 5 is a cross-sectional view showing the semiconductor device according to the embodiment.

FIG. 6 is an enlarged cross-sectional view of a part of the semiconductor device according to the embodiment.

FIG. 7 is a cross-sectional view showing the manufacturing process of the semiconductor device according to the embodiment.

FIG. 8 is a cross-sectional view showing the manufacturing process following FIG. 7.

FIG. 9 is a cross-sectional view showing the manufacturing process following FIG. 8.

FIG. 10 is a cross-sectional view showing the manufacturing process following FIG. 9.

FIG. 11 is a cross-sectional view showing the manufacturing process following FIG. 10.

FIG. 12 is a cross-sectional view showing the manufacturing process following FIG. 11.

FIG. 13 is a cross-sectional view showing the manufacturing process following FIG. 12.

FIG. 14 is a cross-sectional view showing the manufacturing process following FIG. 13.

FIG. 15 is a cross-sectional view showing the manufacturing process following FIG. 14.

FIG. 16 is a cross-sectional view showing the manufacturing process following FIG. 15.

FIG. 17 is a cross-sectional view showing the manufacturing process following FIG. 16.

FIG. 18 is a cross-sectional view showing the manufacturing process following FIG. 17.

FIG. 19 is a cross-sectional view showing the manufacturing process following FIG. 18.

FIG. 20 is a cross-sectional view showing the manufacturing process following FIG. 19.

FIG. 21 is a cross-sectional view showing the manufacturing process following FIG. 20.

FIG. 22 is a cross-sectional view showing the manufacturing process following FIG. 21.

FIG. 23 is a cross-sectional view showing the manufacturing process following FIG. 22.

FIG. 24 is a cross-sectional view showing the manufacturing process following FIG. 23.

FIG. 25 is a cross-sectional view showing the manufacturing process following FIG. 24.

FIG. 26 is a cross-sectional view showing the manufacturing process following FIG. 25.

FIG. 27 is a cross-sectional view showing the semiconductor device in the examined example.

### DETAILED DESCRIPTION

Hereinafter, the embodiment will be described in detail with reference to the drawings. In all the drawings for explaining the embodiments, members having the same functions are denoted by the same reference numerals, and repetitive descriptions thereof are omitted. In the following embodiments, descriptions of the same or similar parts will not be repeated in principle except when particularly necessary.

### <Structure of the Semiconductor Device>

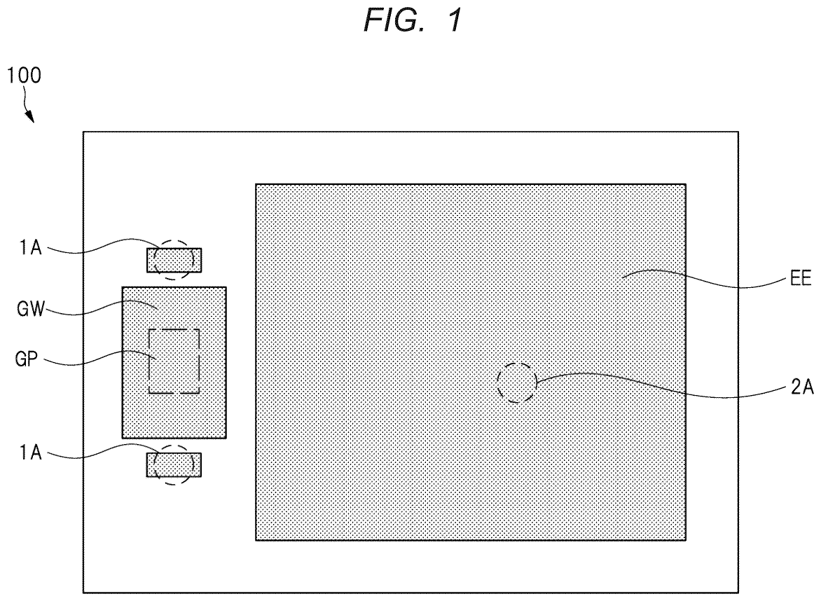

Semiconductor device 100 according to the embodiment will be described below with reference to FIGS. 1 to 6. FIG. 1 is a plan view showing the semiconductor chip, which is the semiconductor device 100.

As shown in FIG. 1, most of the semiconductor device 100 is covered with an emitter electrode EE, and multiple cells constituting the IGBT are formed under the emitter electrode EE. Around the emitter electrode EE, a gate wiring GW is formed. The central part of the emitter electrode EE becomes an emitter pad (not shown), and the central part of the gate wiring becomes a gate pad GP. By connecting external connection terminals such as wire bonding or clips (copper plates) to the emitter pad and the gate pad GP, the semiconductor device 100 is electrically connected to other semiconductor chips or wiring substrates.

The semiconductor device 100 includes regions 1A and 2A, which are different from each other. Region 1A in FIG. 1 is a resistor element region where a resistor element Rg is formed. The resistor element Rg is used for gate resistance, etc. Region 2A in FIG. 1 is a cell region where multiple cells constituting the IGBT are formed.

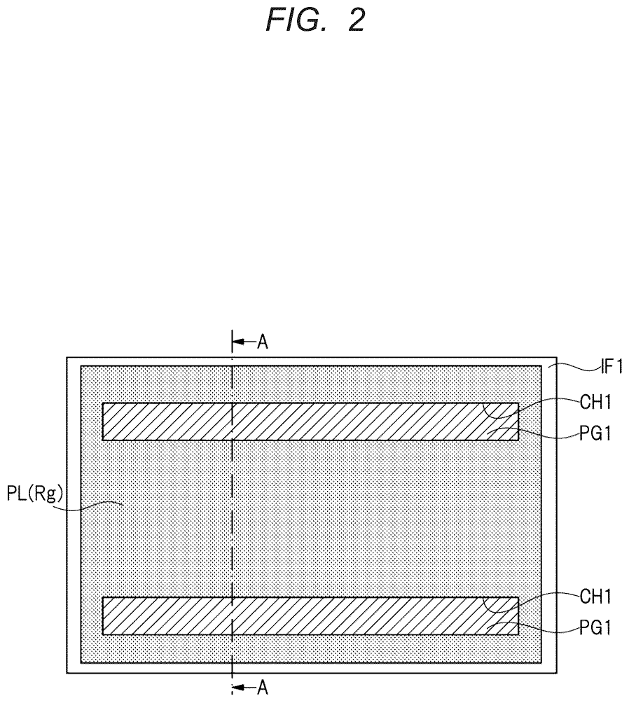

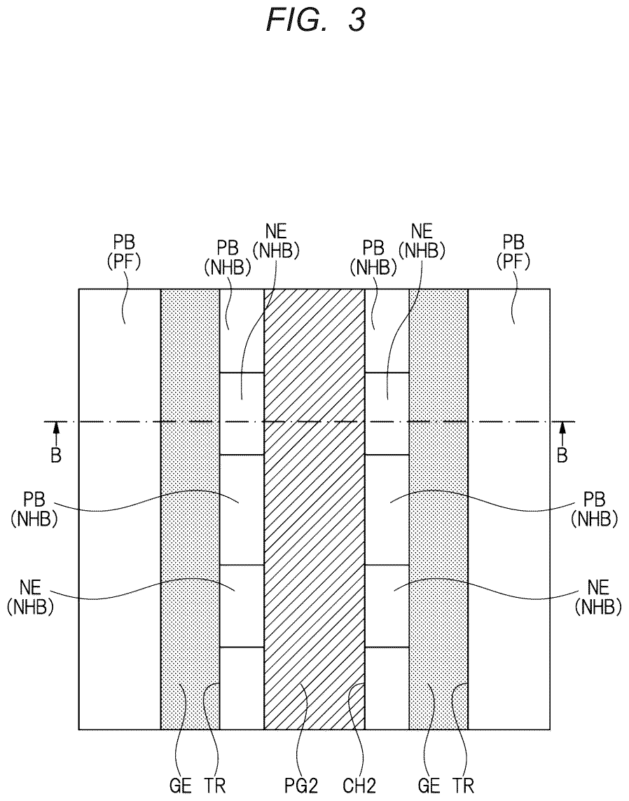

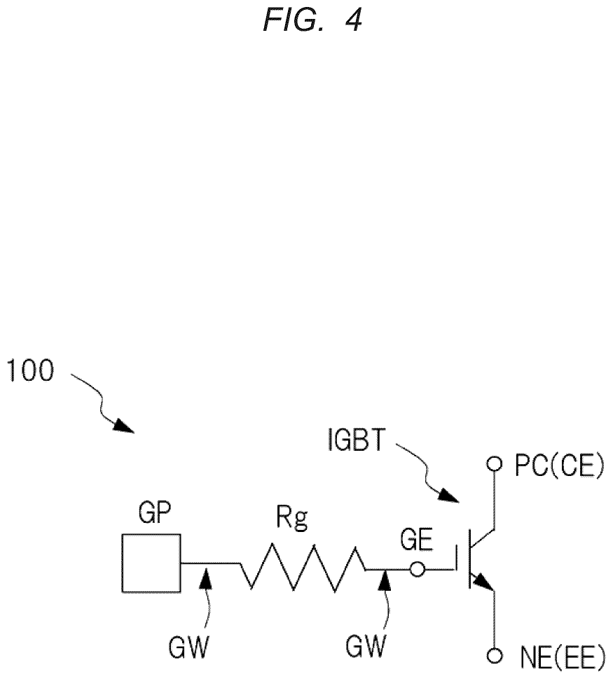

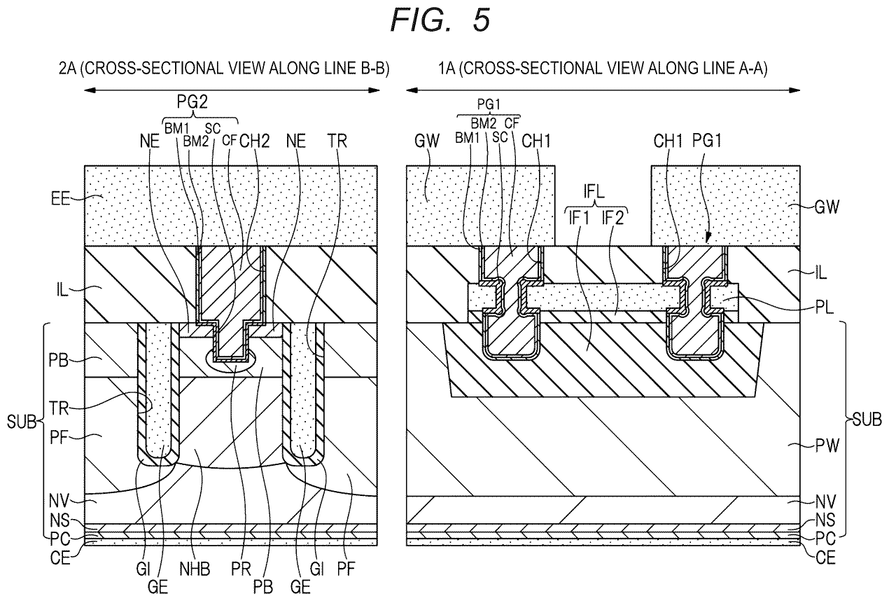

FIG. 2 is a main portion plan view corresponding to region 1A. FIG. 3 is a main portion plan view corresponding to region 2A. FIG. 4 is an equivalent circuit diagram of the semiconductor device 100. FIG. 5 is a cross-sectional view along line A-A of FIG. 2 and line B-B of FIG. 3.

As shown in FIG. 4, the IGBT includes a collector electrode CE, an emitter electrode EE, and a gate electrode GE, and one end of the resistor element Rg is connected to the gate electrode GE via the gate wiring GW. The other end of the resistor element Rg is connected to the gate pad GP via the gate wiring GW. The collector electrode CE is electrically connected to the collector region PC of the IGBT, and the emitter electrode EE is electrically connected to the emitter region NE.

As shown in FIG. 2, the contact hole CH1 has a slit shape in which the opening width in the first direction is wider than the opening width in the second direction orthogonal to the first direction in plain view. That is, the contact hole CH1 forms a rectangular shape in plan view.

However, the planar shape of the contact hole CH1 is not limited to a slit shape, and it may be a dot shape where the opening width in the first direction is the same as the opening width in the second direction. That is, the contact hole CH1 forming a rectangular shape in plain view may be arranged in multiple in the first direction.

Note that the planar shape of the contact hole CH1 often becomes a shape with rounded corners after the resolution of photolithography. Therefore, ultimately, the contact hole CH1 becomes a shape with rounded corners of a rectangle or a circular shape in plan view.

As shown in FIG. 3, the contact hole CH2 has a slit shape in which the opening width in the first direction is narrower than the opening width in the second direction in plan view. That is, the contact hole CH2 forms a rectangular shape in plan view. The contact hole CH2 is arranged between two trenches TR extending in the second direction and intersects with the emitter region NE extending in the first direction.

As shown in FIG. 5, the semiconductor device 100 includes a semiconductor substrate SUB having a low-concentration n-type drift region NV. Here, the n-type semiconductor substrate SUB itself constitutes the drift region NV. Note that the drift region NV may be a laminate of an n-type silicon substrate and a semiconductor layer grown by introducing phosphorus (P) by epitaxial growth on the silicon substrate. In this application, such a laminate is also described as the semiconductor substrate SUB.

On the lower surface side of the semiconductor substrate SUB, an n-type field stop region (impurity region) NS is formed in the semiconductor substrate SUB. The field stop region NS is provided to suppress the depletion layer extending from the pn junction on the upper surface side of the semiconductor substrate SUB from reaching the p-type collector region PC during the turn-off of the IGBT.

On the lower surface side of the semiconductor substrate SUB, a p-type collector region (impurity region) PC is formed in the semiconductor substrate SUB. The collector region PC is located below the field stop region NS.

Below the lower surface of the semiconductor substrate SUB, a collector electrode CE is formed. The collector electrode CE is electrically connected to the collector region PC and supplies a collector potential to the collector region PC. The collector electrode CE is made of metal films such as AlSi film, Ti film, Ni film, and Au film.

### <Resistor Element>

The structure of region 1A will be described below. In the semiconductor device 100, the conductive film PL formed in region 1A is used as the resistor element Rg.

As shown in FIG. 5, a p-type well region PW is formed in the semiconductor substrate SUB on the upper surface side. The well region PW is formed in the same process as the floating region PF of region 2A but is physically separated from the floating region PF.

An insulating layer IFL is formed across the upper surface of the semiconductor substrate SUB and into the interior of the semiconductor substrate SUB. In other words, an insulating layer IFL is formed in the semiconductor substrate SUB, and the lower surface of the insulating layer IFL is positioned below the upper surface of the semiconductor substrate SUB.

The insulation layer IFL includes an insulation film IF1 and an insulation film IF2. The insulation film IF1 is formed inside the semiconductor substrate SUB and is, for example, a silicon oxide film. The insulating film IF2 is formed on the insulating film IF1 and is, for example, a silicon oxide film. The insulating film IF2 has a thinner thickness than the insulating film IF1. The thickness of the insulating film IF1 is, for example, from 500 nm to 600 nm. The thickness of the insulating film IF2 is, for example, from 50 nm to 100 nm.

A conductive film PL is formed on the insulating layer IFL. The conductive film PL is, for example, a polycrystalline silicon film into which p-type impurities are introduced. The thickness of the conductive film PL is, for example, from 150 nm to 250 nm.

An interlayer insulating film IL is formed on the upper surface of the semiconductor substrate SUB to cover the conductive film PL. The interlayer insulating film IL is, for example, a silicon oxide film. The interlayer insulating film IL is subjected to a flattening process to flatten the upper surface of the interlayer insulating film IL. Therefore, the thickness of the interlayer insulating film IL on the upper surface of the semiconductor substrate SUB is, for example, from 600 nm to 800 nm, but the thickness of the interlayer insulating film IL on the upper surface of the conductive film PL is, for example, from 300 nm to 450 nm.

A contact hole CH1 is formed in the interlayer insulating film IL, the conductive film PL, and the insulating layer IFL. The bottom of the contact hole CH1 is located in the insulating layer IFL (in the insulating film IF1). The conductive film PL has a lower surface in contact with the insulating layer IFL (in other words, the insulating film IF2), an upper surface positioned opposite the lower surface and in contact with the interlayer insulating film IL, and a side surface connecting the upper and lower surfaces in the contact hole CH1. A plug PG1 is embedded in the contact hole CH1. In the contact hole CH1, the side surface of the interlayer insulating film IL is separated from the side surface of the conductive film PL so that a part of the upper surface of the conductive film PL is exposed from the interlayer insulating film IL, and the side surface of the insulating layer IFL is separated from the side surface of the conductive film PL so that a part of the lower surface of the conductive film PL is exposed from the insulating layer IFL. For example, the distance between the side of the conductive film PL and the side of the interlayer insulating film IL is 40 nm to 50 nm, and the distance between the side of the conductive film PL and the side of the insulating layer IFL is 30 nm to 40 nm. In other words, in the contact hole CH1, the opening width of the contact hole CH1 formed in the interlayer insulating film IL and the opening width of the contact hole CH1 formed in the insulating layer IFL are wider than the opening width of the contact hole CH1 formed in the conductive film PL.

The plug PG1 includes a barrier metal film BM1, a silicide layer SC, a barrier metal film BM2 formed on the barrier metal film BM1 and the silicide layer SC, and a conductive film CF formed on the barrier metal film BM2. The barrier metal film BM1 is, for example, a titanium film, the silicide layer SC is, for example, a titanium silicide (TiSi) film, and the barrier metal film BM2 is, for example, a titanium nitride film. The conductive film CF is, for example, a tungsten film. The silicide layer SC is a compound of the barrier metal film BM1 and the polycrystalline silicon film constituting the conductive film PL.

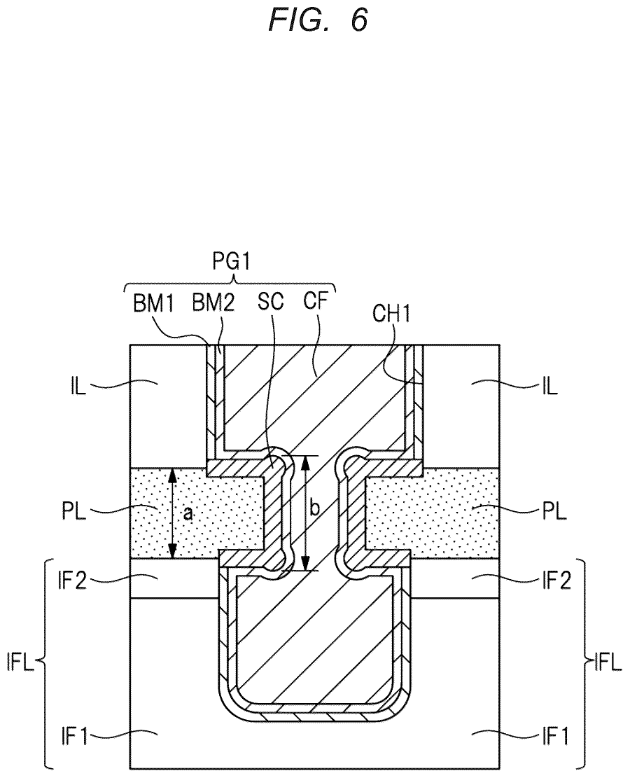

In the contact hole CH1, the silicide layer SC is formed on the side of the conductive film PL, on a part of the upper surface of the conductive film PL exposed from the interlayer insulating film IL, and on a part of the lower surface of the conductive film PL exposed from the insulating layer IFL. In the contact hole CH1, the barrier metal film BM1 is formed on the side of the interlayer insulating film IL and on the side of the insulating layer IFL. As shown in FIG. 6, in the direction perpendicular to the upper surface of the semiconductor substrate SUB, the width b of the silicide layer SC formed on the side of the conductive film PL is greater than the width a of the conductive film PL covered by the interlayer insulating film IL and the insulating layer IFL. This is because, the thickness of the silicide layer SC formed at the corner of the conductive film PL is greater than the thickness of the silicide layer SC formed on the upper, lower, or side surfaces of the conductive film PL.

A gate wiring GW is formed on the interlayer insulating film IL. The conductive film PL is electrically connected to the gate wiring GW via the plug PG1. By configuring the electrical path in the middle of the gate wiring GW with the conductive film PL, the conductive film PL can be used as a resistor element (gate resistor) Rg.

### <Structure of IGBT Cell>

The structure of region 2A will be described below. Here, an IGBT with a vertical trench gate structure is exemplified.

As shown in FIG. 5, a trench TR is formed on the upper surface side of the semiconductor substrate SUB. The depth of the trench TR is, for example, 3 micrometers to 4 micrometers. A gate insulating film GI is formed in the trench TR. The gate electrode GE is formed on the gate insulating film GI so as to fill the trench TR. The gate insulating film GI is, for example, a silicon oxide film, and the gate electrode GE is, for example, a polycrystalline silicon film into which n-type impurities are introduced.

On the upper surface side of the semiconductor substrate SUB, a hole barrier region (impurity region) NHB is formed in the semiconductor substrate SUB between a pair of gate electrodes GE. A p-type base region (impurity region) PB is formed in the hole barrier region NHB. An n-type emitter region (impurity region) NE is formed in the p-type base region PB. The bottom of the base region PB is positioned above the bottom of the trench TR, and the bottom of the emitter region NE is positioned above the bottom of the base region PB.

Also, on the upper surface side of the semiconductor substrate SUB, a p-type floating region (impurity region) PF is formed in the semiconductor substrate SUB outside the region where the hole barrier region NHB is formed. A p-type base region PB is formed in the floating region PF. The floating region PF is formed deeper than the bottom of the trench TR to enhance high voltage resistance characteristics and is formed to cover the bottom of the trench TR.

The interlayer insulating film IL is also formed on the upper surface of the semiconductor substrate SUB in region 2A so as to cover the gate electrode GE, the emitter region NE, and the base region PB. Contact holes CH2 are formed in the interlayer insulating film IL, the emitter region NE, and the base region PB in region 2A. The bottom of the contact hole CH2 is located in the base region PB. A plug PG2 is embedded in the contact hole CH2. The plug PG2 is configured similarly to the plug PG1 and includes a barrier metal film BM1, a silicide layer SC, a barrier metal film BM2, and a conductive film CF.

A p-type high-concentration diffusion region (impurity region) PR is formed around the bottom of the contact hole CH2 in the base region PB. The high-concentration diffusion region PR is provided to reduce the contact resistance with the plug PG2 and to prevent latch-up.

In region 2A, isotropic etching is performed on the interlayer insulating film IL to increase the contact area between the plug PG2 embedded in the contact hole CH2 and the emitter region NE, causing the side of the interlayer insulating film IL to recede. That is, in the contact hole CH2, the side of the interlayer insulating film IL is distanced from the side of the emitter region NE so that a part of the upper surface of the emitter region NE is exposed from the interlayer insulating film IL. In the contact hole CH2, the silicide layer SC is formed on the upper surface of the emitter region NE exposed from the interlayer insulating film IL and on the side surface of the emitter region NE.

An emitter electrode EE is formed on the interlayer insulating film IL. The emitter electrode EE is electrically connected to the emitter region NE, the base region PB, and the high-concentration diffusion region PR via the plug PG2, supplying emitter potential to these regions. Although not shown here, the gate wiring GW is electrically connected to the gate electrode GE via another plug, supplying gate potential to the gate electrode GE.

Such an emitter electrode EE and gate wiring GW are composed of, for example, a TiW film and an aluminum film formed on the TiW film. The aluminum film is the main conductor film of the emitter electrode EE and gate wiring GW and is sufficiently thicker than the TiW film.

### <Main Features of the Embodiment of the Semiconductor Device>

The main features of the embodiment will be described below using FIGS. 5 and 6. FIG. 6 is an enlarged cross-sectional view around the contact hole CH1.

As shown in FIG. 6, in the contact hole CH1, the plug PG1 includes a barrier metal film BM1, a silicide layer SC, a barrier metal film BM2 formed on the barrier metal film BM1 and the silicide layer SC, and a conductive film CF formed on the barrier metal film BM2. In the contact hole CH1, a part of the upper surface of the conductive film PL exposed from the interlayer insulating film IL, a part of the lower surface of the conductive film PL exposed from the insulating layer IFL, and the side of the conductive film PL are covered with the silicide layer SC. In other words, a silicide layer SC is interposed between the polycrystalline silicon film PL constituting the resistor element Rg and the barrier metal film BM2. Therefore, it is possible to suppress the resistance value variation of the resistor element Rg due to the aforementioned interface defects, improving the reliability of the semiconductor device.

Here, in the contact hole CH1, the length of the upper surface of the conductive film PL exposed from the interlayer insulating film IL (40 nm to 50 nm) and the length of the lower surface of the conductive film PL exposed from the insulating layer IFL (30 nm to 40 nm) are smaller compared to the thickness of the conductive film PL (150 nm to 250 nm). Therefore, forming the silicide layer SC on the side of the conductive film PL is effective in suppressing the resistance value variation of the resistor element Rg.

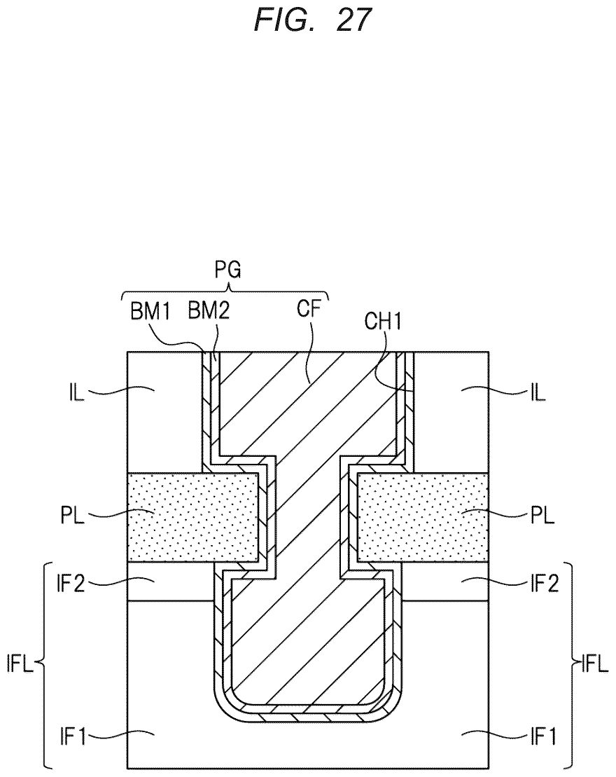

Also, as shown in FIG. 6, the width b of the silicide layer SC formed on the side of the conductive film PL is greater than the width a of the conductive film PL covered by the interlayer insulating film IL and the insulating layer IFL. In other words, the contact area between the silicide layer SC covering the conductive film PL and the barrier metal film BM2 can be increased compared to the contact area between the conductive film PL and the barrier metal film BM1 in the examined example shown in FIG. 27, allowing the resistor element Rg to have low resistance.

### <Manufacturing Method of the Semiconductor Device>

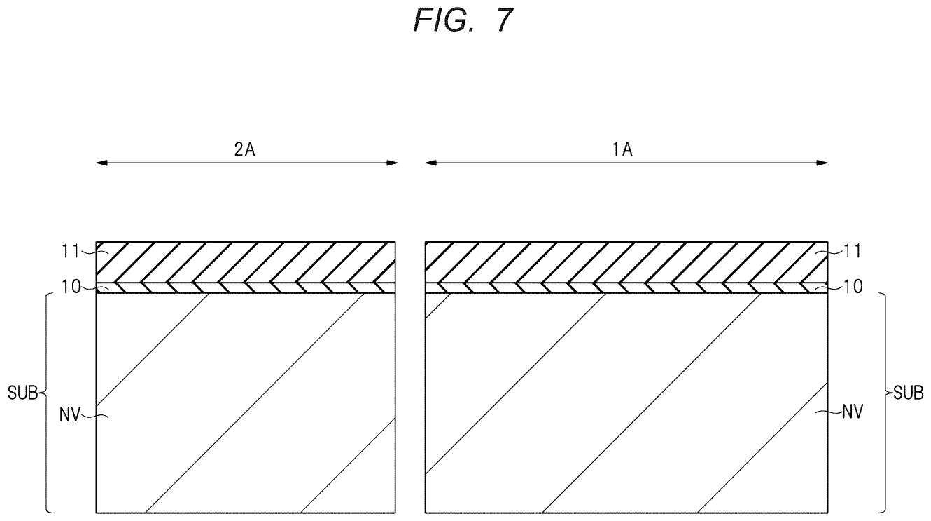

The manufacturing method of the semiconductor device 100 in the embodiment will be described below using FIGS. 7 to 26.

First, as shown in FIG. 7, a semiconductor substrate SUB having an n-type drift region NV is prepared. The semiconductor substrate SUB has an upper surface and a lower surface. Next, a silicon oxide film 10 is formed on the upper surface of the semiconductor substrate SUB, for example, by thermal oxidation. Next, a silicon nitride film 11 is formed on silicon oxide film 10, for example, by the CVD method.

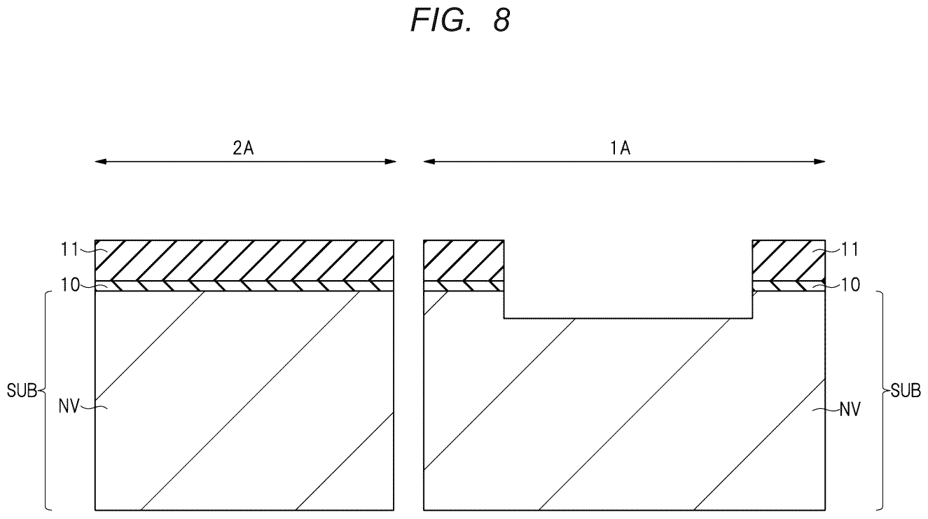

Next, as shown in FIG. 8, by photolithography technology and dry etching processing, the silicon nitride film 11 and the silicon oxide film 10 in region 1A are selectively removed, and openings are formed in silicon nitride film 11 and the silicon oxide film 10. Next, by further performing dry etching processing, a part of the semiconductor substrate SUB exposed in the openings is etched, forming grooves in the semiconductor substrate SUB.

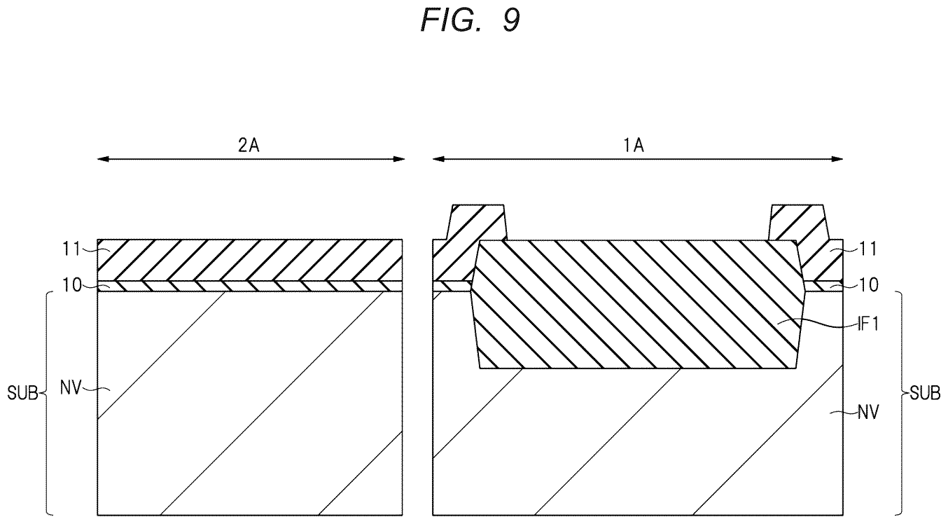

Next, as shown in FIG. 9, by performing thermal oxidation processing on the semiconductor substrate SUB, an insulating film IF1 is formed from the upper surface of the semiconductor substrate SUB to the interior of the semiconductor substrate SUB. In this state, the insulation of film IF1 is formed to a position higher than the upper surface of the semiconductor substrate SUB. That is, an insulation film IF1 with a LOCOS structure is formed on the semiconductor substrate SUB in region 1A. In this state, the thickness of the insulating film IF1 is, for example, 700 nm to 800 nm.

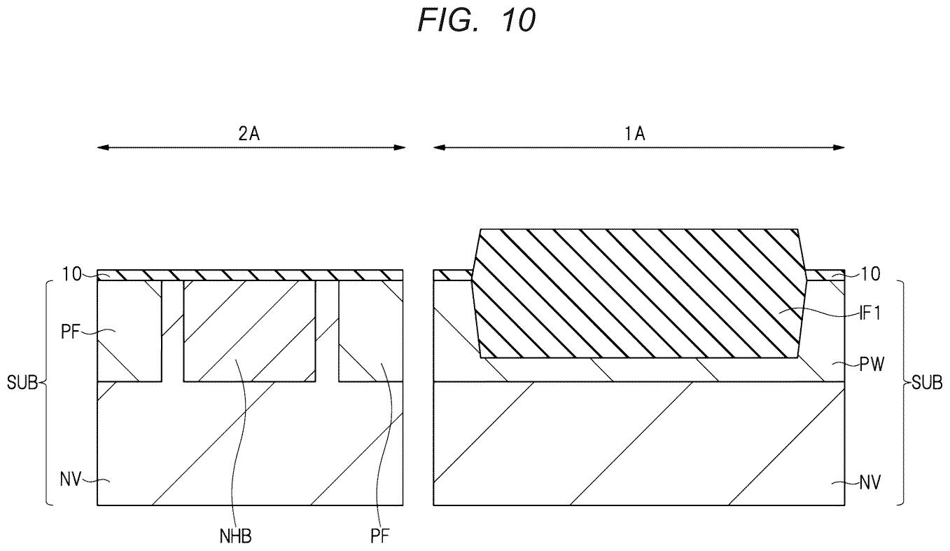

Next, as shown in FIG. 10, the silicon nitride film 11 is removed by isotropic etching using a solution containing phosphoric acid. Then, using photolithography and ion implantation techniques, a p-type well region PW is formed in the semiconductor substrate SUB of region 1A, and a p-type floating region PF is formed in the semiconductor substrate SUB of region 2A. Next, using photolithography and ion implantation techniques, an n-type hole barrier region NHB is formed in the semiconductor substrate SUB of region 2A.

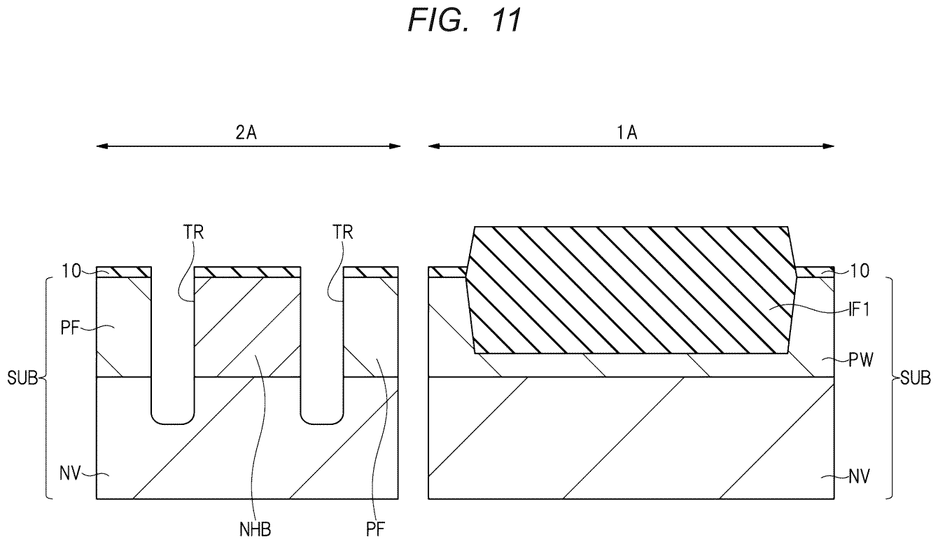

Next, as shown in FIG. 11, a trench TR is formed in the semiconductor substrate SUB of region 2A by photolithography and dry etching processing.

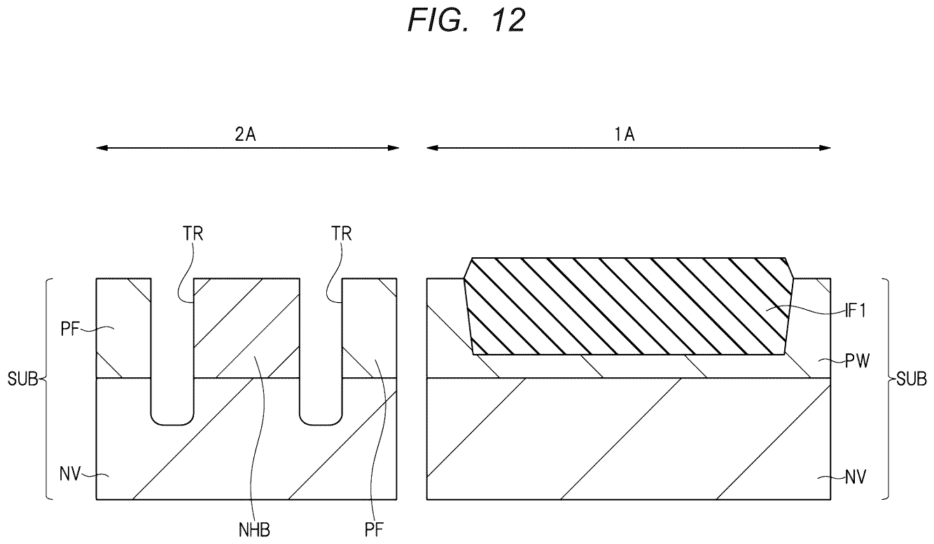

Next, as shown in FIG. 12, the silicon oxide film 10 is removed by isotropic etching using a solution containing hydrofluoric acid. At this time, since the insulating film IF1 is also exposed to isotropic etching, the upper surface of the insulating film IF1 recedes, and the thickness of the insulating film IF1 becomes thinner.

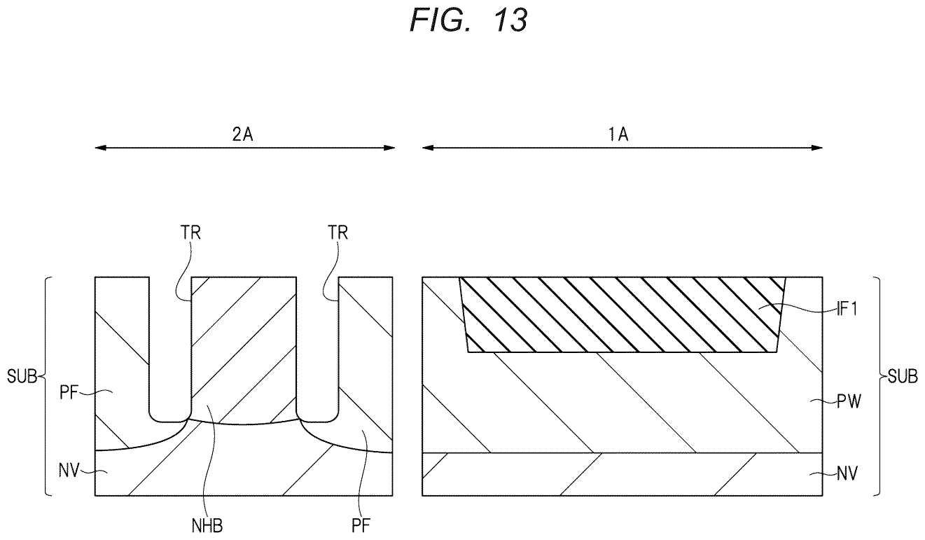

Next, as shown in FIG. 13, performing heat treatment on the semiconductor substrate SUB at, for example, 1000 degrees Celsius to 1200 degrees Celsius, impurities contained in the hole barrier region NHB, the floating region PF, and the well region PW are diffused. Through this heat treatment, the hole barrier region NHB diffuses to the vicinity of the bottom of the trench TR, and the floating region PF diffuses to a position deeper than the bottom of the trench TR, covering the bottom of the trench TR.

Although not shown in the figure, this heat treatment is performed in a state where a sacrificial silicon oxide film is formed on the semiconductor substrate SUB, including the interior of the trench TR. After the heat treatment, the sacrificial silicon oxide film is removed by isotropic etching using a solution containing hydrofluoric acid. At this time, since the insulating film IF1 is also exposed to isotropic etching, the upper surface of the insulating film IF1 recedes, and the thickness of the insulating film IF1 becomes thinner. In this state, the thickness of the insulating film IF1 is, for example, 500 nm to 600 nm.

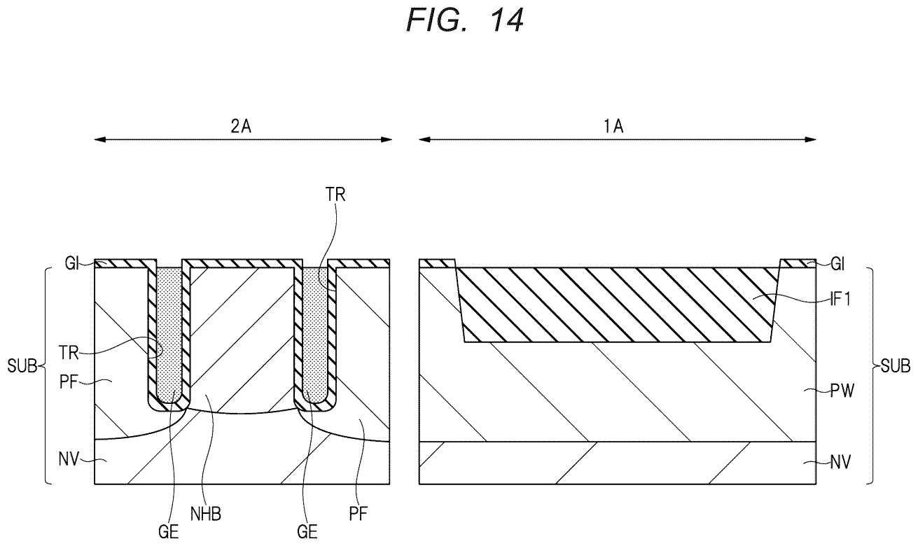

Next, as shown in FIG. 14, a gate insulating film GI is formed inside the trench TR and on the semiconductor substrate SUB. The formation of the gate insulating film GI is performed by thermal oxidation processing. The thickness of the gate insulating film GI is, for example, 100 nm.

Next, a gate electrode GE is formed to fill the inside of the trench TR. To form the gate electrode GE, first, a polycrystalline silicon film with n-type impurities introduced is formed on the gate insulating film GI, for example, by the CVD method. Then, the polycrystalline silicon film formed outside the trench TR is removed by dry etching processing. The polycrystalline silicon film formed inside the trench TR remains as the gate electrode GE.

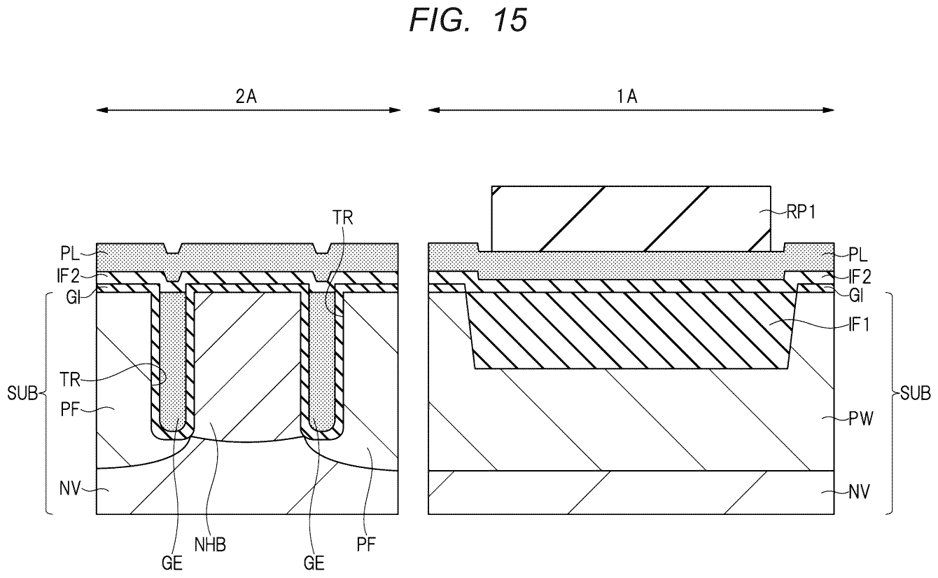

Next, as shown in FIG. 15, an insulating film IF2 is formed on the insulation film IF1, the gate electrode GE, and the gate insulating film GI formed outside the trench TR, for example, by the CVD method. The thickness of the insulating film IF2 is, for example, 50 nm to 100 nm. Next, a conductive film PL is formed on the insulating film IF2, for example, by the CVD method. The thickness of the conductive film PL is, for example, 150 nm to 250 nm.

Next, p-type impurities are introduced into the conductive film PL by ion implantation. Then, a resist pattern RP1 is formed on the conductive film PL in region 1A to selectively cover the conductive film PL located on the insulating film IF1.

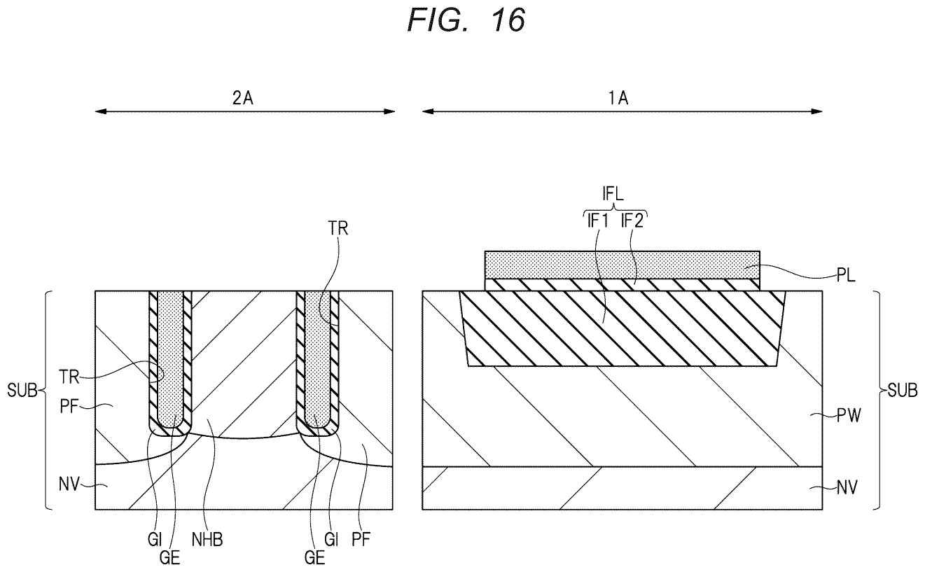

Next, as shown in FIG. 16, by performing dry etching processing using the resist pattern RP1 as a mask, the conductive film PL and the insulating film IF2 are patterned. As a result, a resistor element Rg is formed in region 1A. Also, the patterned insulating film IF2 and insulating film IF1 constitute an insulating layer IFL. Additionally, in this dry etching process, the gate insulating film GI formed outside the trench TR is also removed. Subsequently, the resist pattern RP1 is removed by ashing processing.

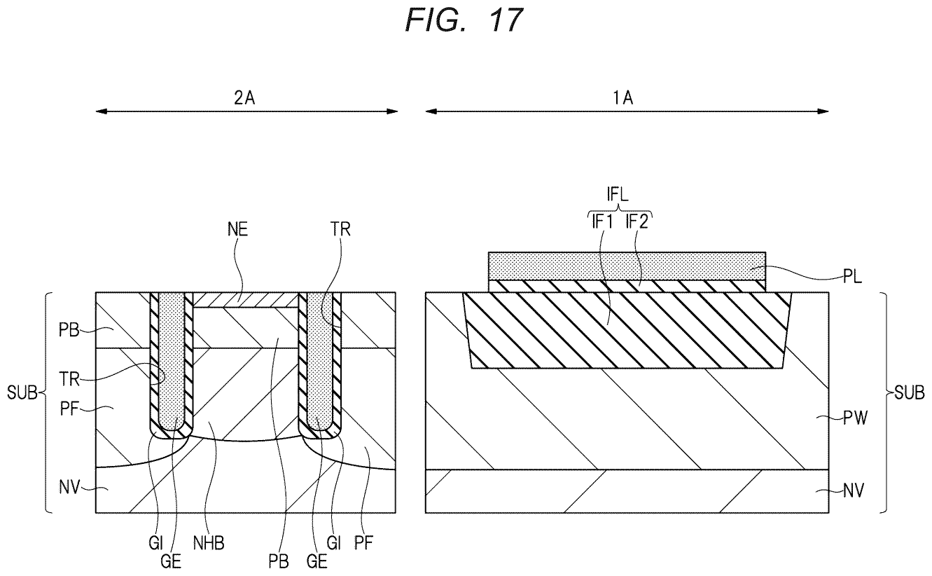

Next, as shown in FIG. 17, on the upper surface side of the semiconductor substrate SUB, a p-type base region PB is formed in the semiconductor substrate SUB (floating region PF and hole barrier region NHB) by photolithography and ion implantation techniques. The bottom of the base region PB is positioned above the bottom of the trench TR. Next, an n-type emitter region NE is formed in the base region PB by photolithography and ion implantation techniques. Thereafter, heat treatment is performed to activate the impurities contained in each impurity region.

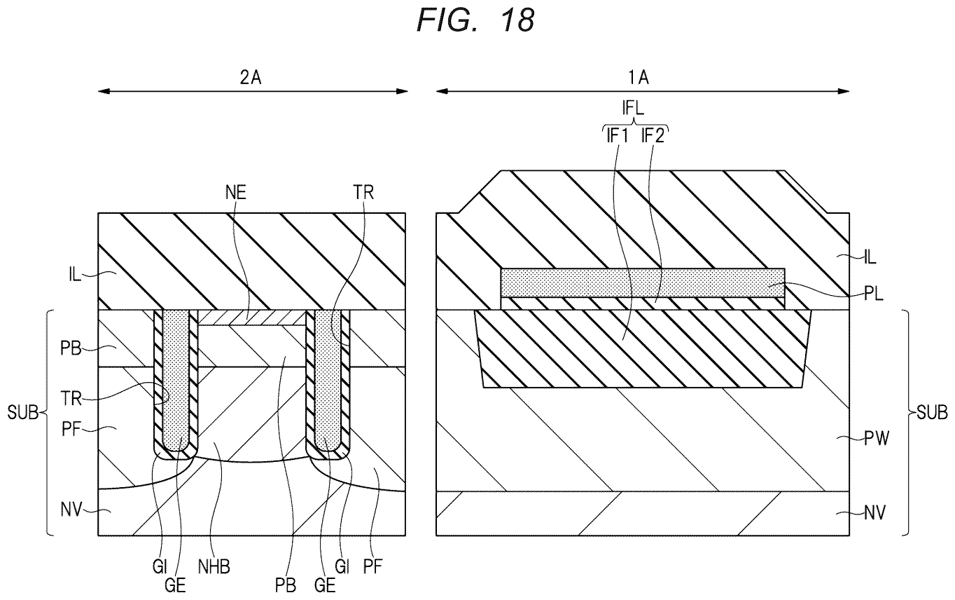

Next, as shown in FIG. 18, an interlayer insulating film IL is formed on the upper surface of the semiconductor substrate SUB in regions 1A and 2A to cover the conductive film PL, the gate electrode GE, the base region PB, and the emitter region NE.

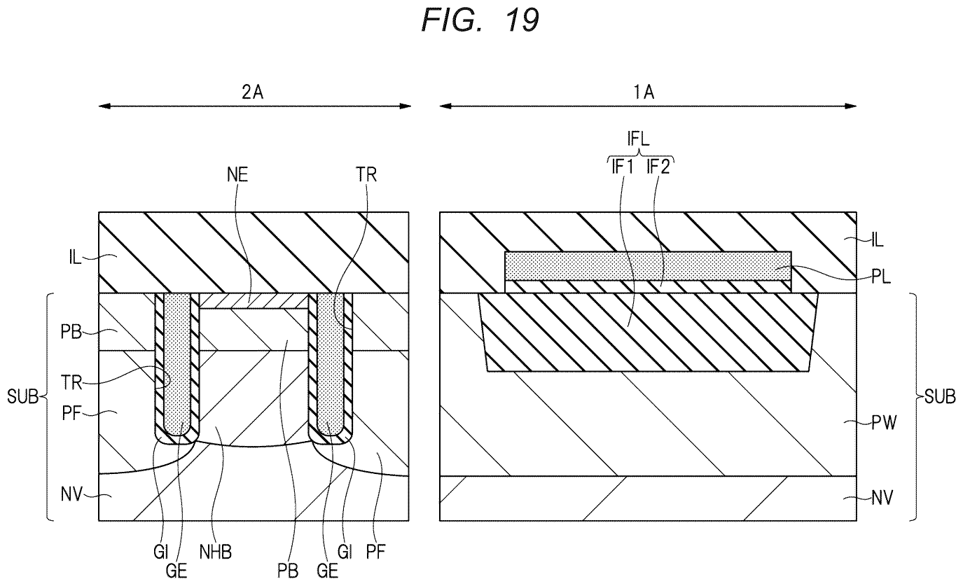

Next, as shown in FIG. 19, to planarize the upper surface of the interlayer insulating film IL, planarization processing is performed on the interlayer insulating film IL in regions 1A and 2A by the CMP method. After the planarization processing, the thickness of the interlayer insulating film IL on the upper surface of the semiconductor substrate SUB is, for example, 600 nm to 800 nm, and the thickness of the interlayer insulating film IL on the upper surface of the conductive film PL is, for example, 300 nm to 450 nm.

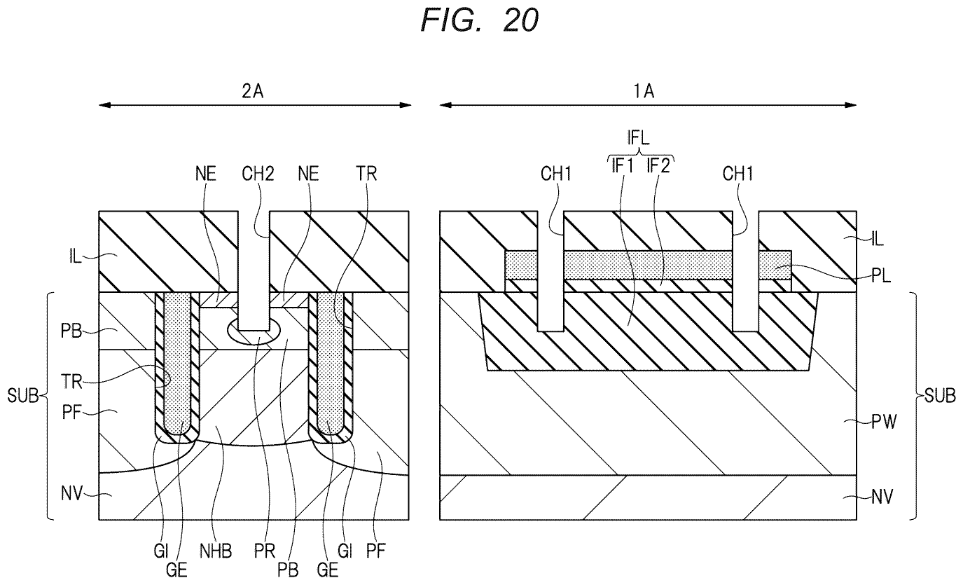

Next, as shown in FIG. 20, by photolithography and anisotropic dry etching processing, contact holes CH1 are formed in region 1A in the interlayer insulating film IL, the conductive film PL, the insulating film IF2, and the insulating film IF1. Simultaneously, in region 2A, contact holes CH2 are formed in the interlayer insulating film IL, the emitter region NE, and the base region PB. Next, a p-type high-concentration diffusion region PR is formed in the base region PB located at the bottom of the contact hole CH2 by ion implantation. Here, the bottom of the contact hole CH1 is located in the insulating film IF1, and the bottom of the contact hole CH2 is located in the base region PB. In the anisotropic dry etching processing, etching gases such as SF6 or CH2F2 are used, but a problem was confirmed where F ions or C ions decomposed in the plasma atmosphere penetrate from the side of the conductive film PL into the interior. Additionally, in region 2A, the penetration of F ions or C ions into the emitter region NE was confirmed.

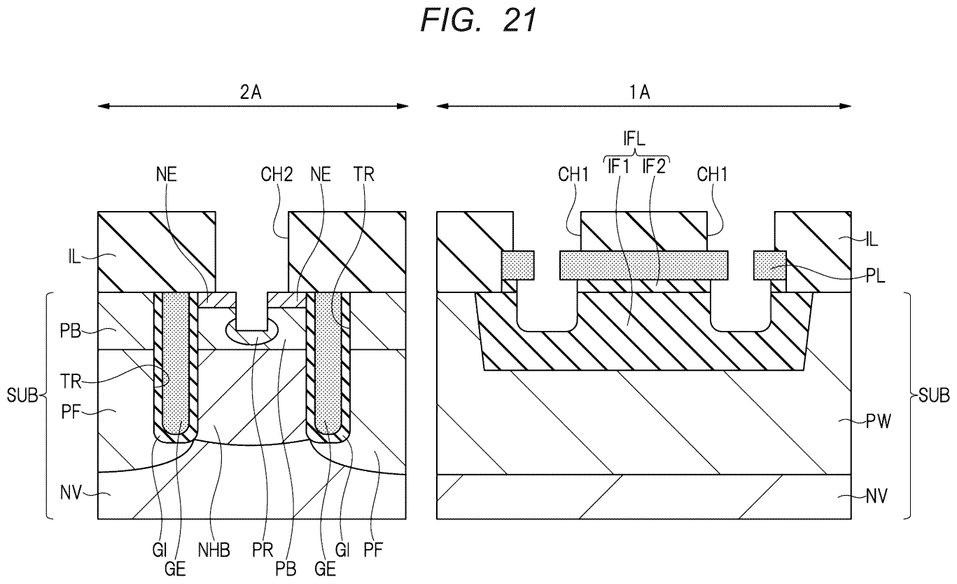

Next, as shown in FIG. 21, isotropic etching processing using a solution containing hydrofluoric acid is performed on the interlayer insulating film IL and the insulating layer IFL (insulating film IF2 and insulating film IF1). Through this isotropic etching processing, in the contact hole CH1, the side surface of the interlayer insulating film IL moves away from the side surface of the conductive film PL so that a part of the upper surface of the conductive film PL is exposed from the interlayer insulating film IL. Also, in the contact hole CH1, the side surface of the insulating layer IFL (the side surface of the insulating film IF1, the side surface of the insulating film IF2) moves away from the side surface of the conductive film PL so that a part of the lower surface of the conductive film PL is exposed from the insulating layer IFL. Additionally, in the contact hole CH2, the side surface of the interlayer insulating film IL moves away from the side surface of the emitter region NE so that a part of the upper surface of the emitter region NE is exposed from the interlayer insulating film IL.

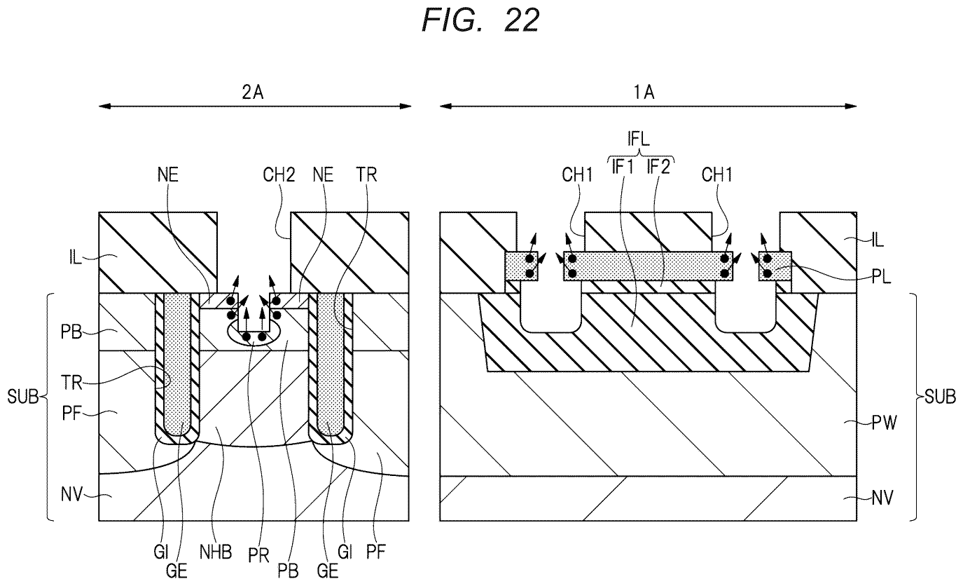

Next, as shown in FIG. 22, hydrogen annealing processing is performed on the semiconductor substrate SUB. The semiconductor substrate SUB is placed on a substrate provided in the chamber of a CVD apparatus. Then, the substrate temperature is set to 600° C. to 650° C., and while introducing hydrogen gas into the chamber, heat treatment is performed on the semiconductor substrate SUB for about 30 seconds. This hydrogen annealing processing discharges F ions or C ions that have penetrated into the conductive film PL and the emitter region NE from the conductive film PL and the emitter region NE. In FIG. 22, black circles indicate F ions or C ions.

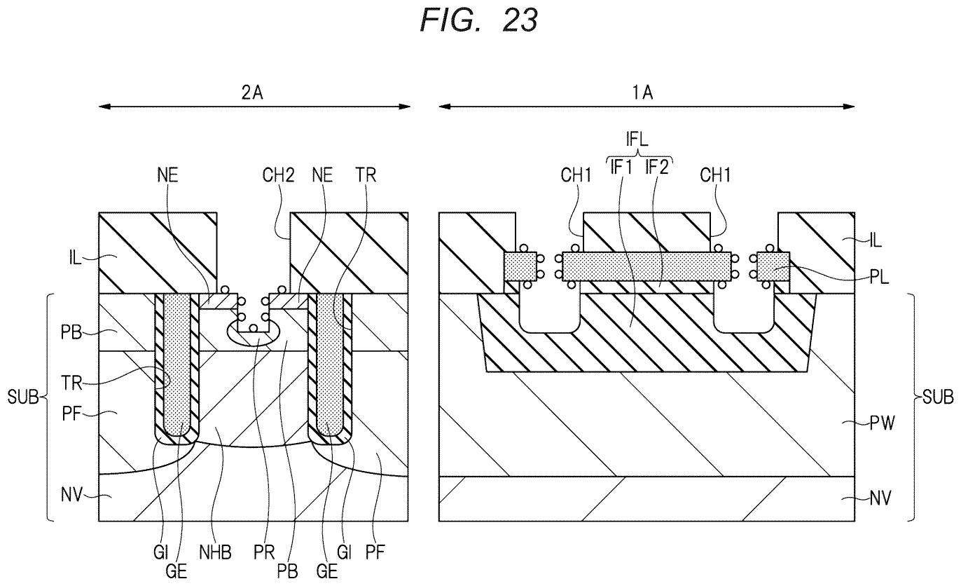

Next, as shown in FIG. 23, hydrogen plasma treatment is applied to the semiconductor substrate SUB. With the semiconductor substrate SUB mounted on the substrate of the above-mentioned CVD apparatus, the substrate temperature is set to 600 to 650 degrees Celsius, and hydrogen gas is introduced into the chamber while plasma is applied to the semiconductor substrate SUB. This hydrogen plasma treatment is carried out for about 5 to 10 seconds. Then, in the contact hole CH1, hydrogen ions are deposited on the side surface of the conductive film PL, a part of the upper surface of the conductive film PL exposed from the interlayer insulating film IL, and a part of the lower surface of the conductive film PL exposed from the insulating layer IFL. In other words, in the contact hole CH1, the dangling bonds on the surface of the polycrystalline silicon film constituting the conductive film PL are terminated with hydrogen ions. In FIG. 23, the white circles indicate hydrogen ions. Additionally, in the contact hole CH2, hydrogen ions are deposited on a part of the upper surface and the side surface of the emitter region NE exposed from the interlayer insulating film IL. In the contact hole CH1, since the upper surface, side surface, and lower surface of the conductive film PL are covered with hydrogen ions, impurities can be prevented from adhering to the upper surface, side surface, and lower surface of the conductive film PL during the barrier metal film BM1 formation process described later. For example, when using a titanium (Ti) film as the barrier metal film BM1, chlorine (Cl) ions contained in the reaction gas titanium tetrachloride (TiCl4) corresponds to impurities. Through the above hydrogen plasma treatment, a high-quality silicide layer SC without impurities can be formed.

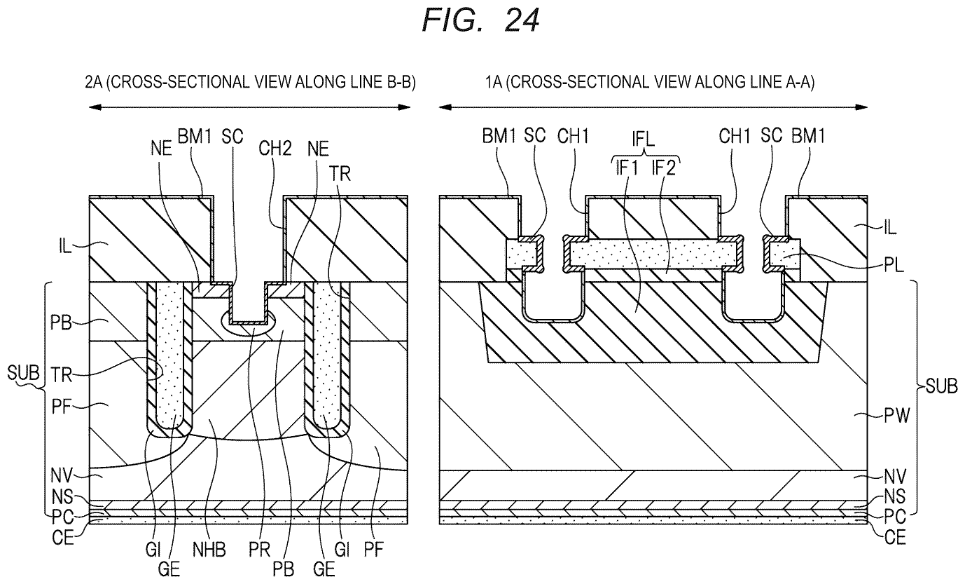

Next, as shown in FIG. 24, the barrier metal film BM1 and the silicide layer SC are formed in the contact holes CH1 and CH2. Note that the barrier metal film BM1 is also formed on the interlayer insulating film IL outside the contact holes CH1 and CH2. With the semiconductor substrate SUB mounted on the substrate of the above-mentioned CVD apparatus, the substrate temperature is set to 600 to 700 degrees Celsius, and a reaction gas is introduced into the chamber while the barrier metal film BM1 is deposited on the semiconductor substrate SUB using the plasma CVD method. For example, the reaction gas is TiCl4 and H2, and the barrier metal film BM1 is a titanium (Ti) film. The film thickness of the barrier metal film BM1 is, for example, 10 nm.

Here, in the contact hole CH1, the barrier metal film BM1 is formed to cover a part of the upper surface of the conductive film PL exposed from the interlayer insulating film IL, a part of the lower surface of the conductive film PL exposed from the insulating layer IFL, the side surface of the conductive film PL, the side surface of the interlayer insulating film IL, and the side surface of the insulating layer IFL. Since the substrate temperature is set to 600 to 700 degrees Celsius, the silicide reaction progresses during the deposition of the barrier metal film BM1. Then, the silicide layer SC is formed on the upper surface of the conductive film PL exposed from the interlayer insulating film IL, the lower surface of the conductive film PL exposed from the insulating layer IFL, and the side surface of the conductive film PL. The silicide layer SC is not formed on the side surface of the interlayer insulating film IL and the side surface of the insulating layer IFL, and the barrier metal film BM1 is formed. Also, in the contact hole CH2, the silicide layer SC is formed at least on the upper surface and the side surface of the emitter region NE exposed from the interlayer insulating film IL. The silicide layer SC is not formed on the side surface of the interlayer insulating film IL, and the barrier metal film BM1 is formed. The silicide layer SC is, for example, a titanium silicide (TiSi) film, and its film thickness is 25 nm.

Note that although the silicide layer SC was formed during the deposition process of the barrier metal film BM1, the silicide layer SC may be formed by performing a heat treatment that progresses the silicide reaction after depositing the barrier metal layer BM1 to the desired film thickness. In other words, the barrier metal film BM1 is formed by the CVD method at a relatively low substrate temperature (400 to 500 degrees Celsius), and then a heat treatment at 600 to 700 degrees Celsius is performed to form the silicide layer SC.

Note that if F ions or C ions remain in the conductive film PL or the emitter region NE, it becomes difficult to form the silicide layer SC on the conductive film PL or the emitter region NE. However, by performing the above hydrogen annealing treatment before forming the silicide layer SC, it becomes possible to form the silicide layer SC on the conductive film PL or the emitter region NE.

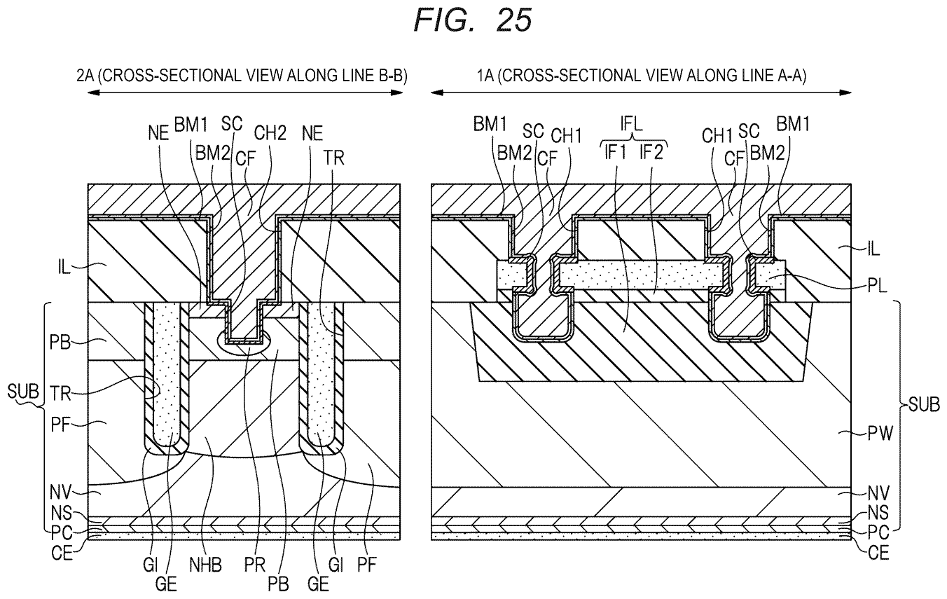

Next, as shown in FIG. 25, the barrier metal film BM2 is formed by the CVD method on the interlayer insulating film IL, including inside the contact holes CH1 and CH2. The barrier metal film BM2 is, for example, a titanium nitride (TiN) film. The barrier metal film BM2 is in contact with the silicide layer SC formed on the upper surface, side surface, and lower surface of the conductive film PL in the contact hole CH1. Furthermore, the barrier metal film BM2 is in contact with the barrier metal film BM1 formed on the side surface of the interlayer insulating film IL and the side surface of the insulating layer IFL in the contact hole CH1. In the contact hole CH2, it is in contact with the silicide layer SC formed on the upper surface and the side surface of the emitter region NE exposed from the interlayer insulating film IL. Furthermore, it is in contact with the barrier metal film BM1 formed on the side surface of the interlayer insulating film IL.

Next, the conductive film CF is formed on the barrier metal film BM2 to embed the inside of the contact holes CH1 and CH2. The conductive film CF is, for example, a tungsten (W) film and is formed using WF₆ gas.

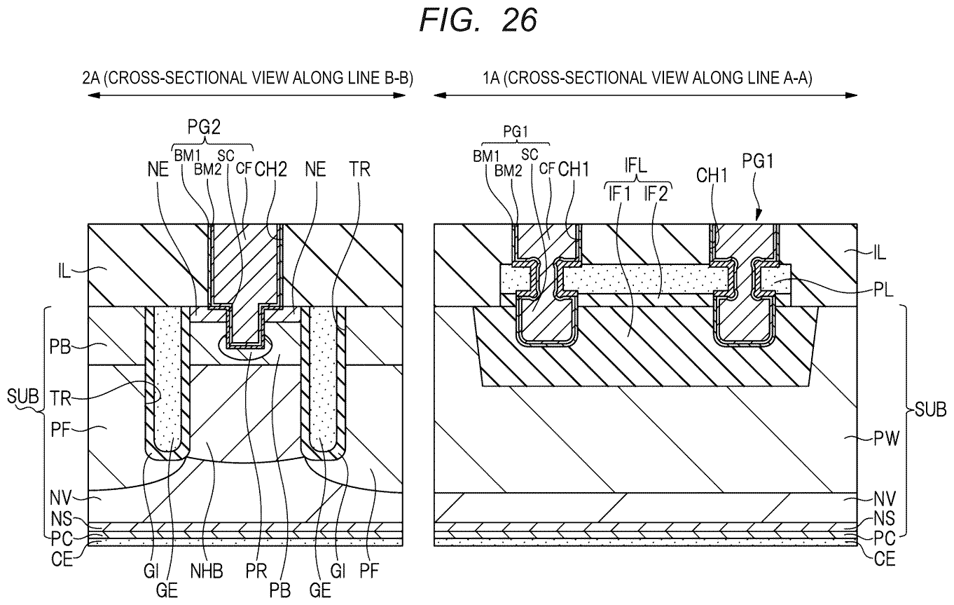

Next, as shown in FIG. 26, the conductive film CF, the barrier metal film BM2, and the barrier metal film BM1 formed outside the contact holes CH1 and CH2 are removed by polishing treatment using the CMP method or anisotropic dry etching treatment. As a result, the plug PG1, which includes the conductive film CF, the barrier metal film BM2, the silicide layer SC, and the barrier metal film BM1, is embedded in the contact hole CH1. Then, the plug PG2, which includes the conductive film CF, the barrier metal film BM2, the silicide layer SC, and the barrier metal film BM1, is embedded in the contact hole CH2.

Next, as shown in FIG. 5, the gate wiring GW is formed on the interlayer insulating film IL in region 1A, and the emitter electrode EE is formed on the interlayer insulating film IL in region 2A. First, for example, by the sputtering method, a TiW film is formed on the interlayer insulating film IL, and then, for example, by the sputtering method, an aluminum film is formed on the TiW film. Next, by patterning the TiW film and the aluminum film using photolithography technology and dry etching treatment, the gate wiring GW and the emitter electrode EE are formed.

Next, on the lower surface side of the semiconductor substrate SUB, the field stop region NS, the collector region PC, and the collector electrode CE are formed. First, a support tape is attached to the upper surface side of the semiconductor substrate SUB, and the lower surface of the semiconductor substrate SUB is ground to thin the thickness of the semiconductor substrate SUB to, for example, 80 μm to 90 μm. Then, by performing an etching treatment using a solution containing hydrofluoric acid on the lower surface of the semiconductor substrate SUB, the grinding damage layer is removed. Then, by performing ion implantation from the lower surface side of the semiconductor substrate SUB, the n-type field stop region NS and the p-type collector region PC are formed. After these ion implantations, laser annealing is performed to activate the impurities contained in the field stop region NS and the collector region PC. Next, on the lower surface side of the semiconductor substrate SUB, for example, by the sputtering method, metal films such as AlSi film, Ti film, Ni film, and Au film are formed under the lower surface of the semiconductor substrate SUB. This metal film becomes the collector electrode CE.

As described above, the semiconductor device 100 according to the embodiment is manufactured.

Next, the features of the manufacturing method of the semiconductor device according to the embodiment will be described.

In the contact hole CH1, before forming the barrier metal film BM1 on a part of the conductive film PL exposed from the interlayer insulating film IL and the insulating layer IFL, hydrogen annealing treatment is applied to a part of the conductive film PL exposed from the interlayer insulating film IL and the insulating layer IFL. Through this hydrogen annealing treatment, F ions or C ions that have penetrated into the conductive film PL during the above anisotropic dry etching treatment can be removed from the conductive film PL, allowing the silicide layer SC to be formed on the surface of the conductive film PL. Then, by electrically connecting the conductive film PL with the barrier metal film BM2 and the conductive film CF through the silicide layer SC, the variation in the resistance value of the resistor element Rg is suppressed, and the reliability of the semiconductor device is improved. Also, in the contact hole CH2, before forming the barrier metal film BM1 on the upper surface and the side surface of the emitter region NE exposed from the interlayer insulating film IL, hydrogen annealing treatment is applied to the upper surface and the side surface of the emitter region NE exposed from the interlayer insulating film IL. Through this hydrogen annealing treatment, F ions or C ions that have penetrated into the emitter region NE during the above anisotropic dry etching treatment can be removed from the emitter region NE, allowing the silicide layer SC to be formed on the upper surface and the side surface of the emitter region NE.

By performing the above hydrogen annealing treatment, the silicide layer SC can be formed on the conductive film PL and the emitter region NE. Therefore, in the manufacturing method of the semiconductor device according to the embodiment, the hydrogen plasma treatment described using FIG. 23 may be omitted. However, by performing hydrogen plasma treatment between the above-mentioned hydrogen annealing process and the formation of the barrier metal film BM1, it is possible to improve the quality of the silicide layer SC, suppress the resistance value variation of the resistor element Rg, and enhance the reliability of the semiconductor device.

As a modified example, before the above hydrogen annealing process, sputter etching treatment may be applied to a part of the conductive film PL exposed from the interlayer insulating film IL and the insulating layer IFL. In the sputter etching process, the semiconductor substrate SUB is exposed to a plasma atmosphere containing an inert gas (Ar or N2). Since the upper surface of the conductive film PL exposed from the interlayer insulating film IL is etched away, the F ions or C ions contained in the conductive film PL can be reduced.

Although the present invention has been described based on the above embodiments, it is not limited to these embodiments and various modifications can be made without departing from the gist thereof.

For example, a diode element may be formed in the conductive film PL instead of the resistor element Rg.

Furthermore, although an IGBT is exemplified as a device formed in region 2A, the technology disclosed in the above embodiments is not limited to IGBTs and can also be applied to power MOSFETs with a vertical trench gate structure.

What is claimed is:

1. A semiconductor device comprising:
a semiconductor substrate having an upper surface and a lower surface;
an insulating film formed on the upper surface of the semiconductor substrate;
a first conductive film formed on the insulating film;
an interlayer insulating film formed on the upper surface of the semiconductor substrate so as to cover the first conductive film;
a first contact hole formed in the interlayer insulating film, in the first conductive film, and in the insulating film; and
a first plug embedded in the first contact hole,
wherein in the first contact hole, a first side surface of the interlayer insulating film is spaced apart from a second side surface of the first conductive film so that a part of an upper surface of the first conductive film is exposed from the interlayer insulating film,
wherein in the first contact hole, a third side surface of the insulating film is spaced apart from the second side surface of the first conductive film so that a part of a lower surface of the first conductive film is exposed from the insulating film, and
wherein the first plug includes:
a first silicide layer formed on the second side surface of the first conductive film;
a first barrier metal film formed on the first silicide layer; and
a second conductive film formed on the first barrier metal film.

2. The semiconductor device according to claim 1,
wherein the first silicide layer is formed in the first contact hole to cover a part of the upper surface of the first conductive film exposed from the first side surface of the interlayer insulating film and a part of the lower surface of the first conductive film exposed from the third side surface of the insulating film.

3. The semiconductor device according to claim 2,
wherein, in a direction perpendicular to the upper surface of the semiconductor substrate, a first width of the first silicide layer formed on the second side surface of the first conductive film is greater than a second width of the first conductive film in a region between the interlayer insulating film and the insulating film.

4. The semiconductor device according to claim 2,
wherein the first plug includes a second barrier metal film formed on the first side surface of the interlayer insulating film and the third side surface of the insulating film, in the first contact hole.

5. The semiconductor device according to claim 4,
wherein the first conductive film is a polycrystalline silicon film.

6. The semiconductor device according to claim 5,
wherein the second barrier metal film is a titanium film, a nickel film, a tantalum film, or a tungsten film.

7. The semiconductor device according to claim 6,
wherein the first silicide layer is an alloy film of the polycrystalline silicon film and the second barrier metal film.

8. The semiconductor device according to claim 7,
wherein the first barrier metal film is a titanium nitride film, and
wherein the second conductive film is a tungsten film.

9. The semiconductor device according to claim 1, further comprising:
a first region where the first conductive film is formed;
a second region different from the first region;
a trench formed in the semiconductor substrate in the second region on an upper surface side of the semiconductor substrate;
a gate insulating film formed in the trench;
a gate electrode formed on the gate insulating film to fill the trench;
a first impurity region of a first conductivity type formed in the semiconductor substrate in the second region on the upper surface side of the semiconductor substrate such that a bottom of the first impurity region is positioned above a bottom of the trench; and
a second impurity region of a second conductivity type opposite to the first conductivity type, formed in the first impurity region,
wherein the interlayer insulating film is also formed on the upper surface of the semiconductor substrate in the second region to cover the gate electrode, the first impurity region, and the second impurity region,
wherein a second contact hole is formed in the interlayer insulating film, in the second impurity region, and in the first impurity region in the second region such that a bottom of the second contact hole is positioned in the first impurity region,
wherein, in the second contact hole, a fourth side surface of the interlayer insulating film is spaced apart from a fifth side surface of the second impurity region such that a part of an upper surface of the second impurity region is exposed from the interlayer insulating film,
wherein a second plug is embedded in the second contact hole, and
wherein the second plug includes:
a second silicide layer formed on a part of the upper surface of the second impurity region and on the fifth side surface of the second impurity region;
a third barrier metal film formed on the second silicide layer; and
a third conductive film formed on the third barrier metal film.

10. The semiconductor device according to claim 9, further comprising:
a gate wiring formed on the interlayer insulating film in the first region and electrically connected to the gate electrode; and
an emitter electrode formed on the interlayer insulating film in the second region,
wherein the first impurity region and the second impurity region are electrically connected to the emitter electrode via the second plug, and
wherein the first conductive film is electrically connected to the gate wiring via the first plug.

11. A method of manufacturing a semiconductor device, the method comprising:
(a) preparing a semiconductor substrate having an upper surface and a lower surface;
(b) after the (a), forming an insulating film on the semiconductor substrate;
(c) after the (b), forming a first conductive film on the insulating film;
(d) after the (c), forming an interlayer insulating film on the upper surface of the semiconductor substrate to cover the first conductive film;
(e) after the (d), performing anisotropic dry etching on the interlayer insulating film, on the first conductive film, and on the insulating film to form a first contact hole;
(f) after the (e), performing isotropic etching on the interlayer insulating film and on the insulating film; and
(g) after the (f), filling the first contact hole with a first plug,
wherein, by the (f), a first side surface of the interlayer insulating film is distanced from a second side surface of the first conductive film such that a part of an upper surface of the first conductive film is exposed from the interlayer insulating film,
wherein, by the (f), a third side surface of the insulating film is distanced from the second side surface of the first conductive film such that a part of a lower surface of the first conductive film is exposed from the insulating film in the first contact hole,
wherein the (g) includes:
(g1) after the (f), performing heat treatment on the semiconductor substrate in a hydrogen atmosphere;
(g2) after the (g1), forming a first silicide layer on the second side surface of the first conductive film, in the first contact hole;
(g3) after the (g2), forming a first barrier metal film on the first silicide layer; and
(g4) after the (g3), forming a second conductive film on the first barrier metal film.

12. The method according to claim 11,
wherein, in the (g2), the first silicide layer is formed in the first contact hole to cover a part of the upper surface of the first conductive film exposed from the first side surface of the interlayer insulating film and a part of the lower surface of the first conductive film exposed from the third side surface of the insulating film.

13. The method according to claim 12,
wherein in the (g2), the first silicide layer is formed by deposit a second barrier metal film in the first contact hole using plasma CVD method with a substrate temperature set between 600 degrees Celsius and 700 degrees Celsius.

14. The method according to claim 12, further comprising:
(g5) between the (g1) and the (g2), attaching hydrogen ions to a part of the upper surface of the first conductive film exposed from the first side surface of the interlayer insulating film, to the second side surface of the first conductive film, and to a part of the lower surface of the first conductive film exposed from the third side surface of the insulating film, in the first contact hole.

15. The method according to claim 12, further comprising:
(g6) between the (f) and the (g1), performing a sputter etching process using an inert gas on a part of the upper surface of the first conductive film exposed from the first side surface of the interlayer insulating film, on the second side surface of the first conductive film, and on a part of the lower surface of the first conductive film exposed from the third side surface of the insulating film, in the first contact hole.

16. A method of manufacturing a semiconductor device having a first region and a second region different from the first region, the method comprising:
(a) preparing a semiconductor substrate having an upper surface and a lower surface;
(b) after the (a), forming a first insulating film across an interior of the semiconductor substrate from a position higher than the upper surface of the semiconductor substrate, in the first region;
(c) after the (b), forming a trench in the semiconductor substrate in the second region on an upper surface side of the semiconductor substrate;
(d) after the (c), forming a gate insulating film in the trench;
(e) after the (d), forming a gate electrode on the gate insulating film so as to fill the trench;
(f) after the (e), forming a second insulating film having a thickness thinner than the first insulating film on the upper surface of the semiconductor substrate in the first region and in the second region, so as to cover the first insulating film in the first region and the gate electrode in the second region;
(g) after the (f), forming a first conductive film on the second insulating film in the first region and in the second region;
(h) after the (g), removing the first conductive film and the second insulating film so that the first conductive film and the second insulating film are selectively left on the first insulating film;
(i) after the (h), forming a first impurity region of a first conductivity type in the semiconductor substrate in the second region on the upper surface side of the semiconductor substrate, such that a bottom of the first impurity region positioned above a bottom of the trench;
(j) after the (i), forming a second impurity region of a second conductivity type opposite to the first conductivity type in the first impurity region;
(k) after the (j), forming an interlayer insulating film on the upper surface of the semiconductor substrate in the first region and in the second region, so as to cover the first conductive film in the first region and the gate electrode, the first impurity region, and the second impurity region in the second region;
(l) after the (k), performing a planarization process on the interlayer insulating film in the first region and in the second region by CMP method to flatten the upper surface of the interlayer insulating film;
(m) after the (l), performing anisotropic dry etching on the interlayer insulating film, on the first conductive film, the on second insulating film, and on the first insulating film to form a first contact hole in the interlayer insulating film, in the first conductive film, in the second insulating film, and in the first insulating film in the first region such that a bottom of the first contact hole positioned in the first insulating film, and to form a second contact hole in the interlayer insulating film, in the second impurity region, and in the first impurity region in the second region such that a bottom of the second contact hole positioned in the first impurity region;
(n) after the (m), performing isotropic etching on the interlayer insulating film, on the second insulating film, and on the first insulating film; and
(o) after the (n), filling the first contact hole with a first plug and filling the second contact hole with a second plug,
wherein, by the (n), in the first contact hole, a first side surface of the interlayer insulating film is separated from a second side surface of the first conductive film so that a part of an upper surface of the first conductive film is exposed from the interlayer insulating film,
wherein, by the (n), in the first contact hole, a third side surface of the first insulating film and the second insulating film are separated from the second side surface of the first conductive film so that a part of a lower surface of the first conductive film is exposed from the first insulating film and the second insulating film,
wherein, by the (n), in the second contact hole, a fourth side surface of the interlayer insulating film is spaced apart from a fifth side surface of the second impurity region so that a part of an upper surface of the second impurity region is exposed from the interlayer insulating film, and
wherein the (o) includes:
(o1) after the (n), performing heat treatment on the semiconductor substrate in a hydrogen atmosphere;
(o2) after the (o1), forming a first silicide layer on the second side surface of the first conductive film in the first contact hole and forming a second silicide layer on a part of an upper surface of the second impurity region and on the fifth side surface of the second impurity region in the second contact hole;
(o3) after the (o2), forming a first barrier metal film on the first silicide layer and on the second silicide layer; and
(o4) after the (o3), forming a second conductive film on the first barrier metal film.

17. The method according to claim 16,
wherein, in the (o2), the first silicide layer is formed in the first contact hole to cover a part of an upper surface of the first conductive film exposed from the first side surface of the interlayer insulating film and a part of a lower surface of the first conductive film exposed from the third side surface of the second insulating film.

18. The method according to claim 17,
wherein in the (o2), the first silicide layer and the second silicide layer are formed by depositing a second barrier metal film in the first contact hole and in the second contact hole using plasma CVD method with a substrate temperature set between 600 degrees Celsius and 700 degrees Celsius.

19. The method according to claim 17, further comprising:
(o5) between the (o1) and the (o2), attaching hydrogen ions to a part of an upper surface of the first conductive film exposed from the first side surface of the interlayer insulating film, to the second side surface of the first conductive film, and to a part of a lower surface of the first conductive film exposed from the third side surface of the second insulating film, in the first contact hole, and to a part of an upper surface of the second impurity region and to a fifth side surface of the second impurity region in the second contact hole.

20. The method according to claim 19, further comprising:
(o6) between the (n) and the (o1), performing a sputter etching process using an inert gas on a part of an upper surface of the first conductive film exposed from the first side surface of the interlayer insulating film, on the second side surface of the first conductive film, and on a part of a lower surface of the first conductive film exposed from the third side surface of the second insulating film, in the first contact hole, on a part of an upper surface of the second impurity region and on a fifth side surface of the second impurity region in the second contact hole.
